(19) United States
(12) Patent Application Publication
(10) Pub. No.: US 2010/0109044 A1
(43) Pub. Date: May 6, 2010

(54) Optimized Compressive SiGe Channel PMOS Transistor with Engineered Ge Profile and Optimized Silicon Cap Layer

(76) Inventors: Daniel G. Tekleab, Wappingers Fallls, NY (US); Srikanth B. Samavedam, Fishkill, NY (US)

Correspondence Address: HAMILTON & TERRILE, LLP - FREESCALE, P.O. BOX 203518, AUSTIN, TX, 78720, US

(21) Appl. No.: 12/261,589

(22) Filed: Oct. 30, 2008

(51) Int. Cl. H01L 29/778; H01L 21/336; H01L 21/8238

(52) U.S. Cl. 257/190; 438/285; 438/197; 257/E29.246; 257/E21.632; 257/E21.403

(57) ABSTRACT

A semiconductor process and apparatus includes forming PMOS transistors (72) with enhanced hole mobility in the channel region by epitaxially growing a bi-axially stressed forward graded silicon germanium channel region layer (22) and a counter-doped silicon cap layer (23) prior to forming a PMOS gate structure (34) and associated source/drain regions (38, 40) in the channel region layer(s).

### BACKGROUND OF THE INVENTION

1. Field of the Invention

The present invention is directed in general to the field of semiconductor fabrication and integrated circuits. In one aspect, the present invention relates to forming PMOS field effect transistors (FETs) as part of a complementary metal oxide semiconductor (CMOS) fabrication process.

2. Description of the Related Art

CMOS devices, such as NMOS or PMOS transistors, have conventionally been fabricated on semiconductor wafers with a surface crystallographic orientation of (100), and its equivalent orientations, e.g., (010), (001), (00-1), where the transistor devices are typically fabricated with a <100> crystal channel orientation (i.e., on 45 degree rotated wafer or substrate). The channel defines the dominant direction of electric current flow through the device, and the mobility of the carriers generating the current determines the performance of the devices. While it is possible to improve carrier mobility by intentionally stressing the channels of NMOS and/or PMOS transistors, it is difficult to simultaneously improve the carrier mobility for both types of devices formed on a uniformly-strained substrate because PMOS carrier mobility and NMOS carrier mobility are optimized under different types of stress. For example, some CMOS device fabrication processes have attempted to enhance electron and hole mobilities by using strained (e.g. with a bi-axial tensile strain) silicon for the channel region that is formed by depositing a layer of silicon on a template layer (e.g., silicon germanium) which is relaxed prior to depositing the silicon layer, thereby inducing tensile stress in the deposited layer of silicon. It has also been discovered that the tensile stress in the deposited silicon layer may be enhanced by forming a relatively thick template silicon germanium (SiGe) layer that is graded to have a higher concentration of germanium in a lower portion of the template SiGe layer (e.g., backward graded). Such processes enhance the electron mobility for NMOS devices by creating tensile stress in NMOS transistor channels, but PMOS devices are insensitive to any uniaxial stress in the channel direction for devices fabricated along the <100> direction. On the other hand, attempts have been made to selectively improve hole mobility in PMOS devices, such as by forming PMOS channel regions with a compressively stressed SiGe layer over a silicon substrate. However, such compressive SiGe channel PMOS devices exhibit a higher subthreshold slope (SS) and higher voltage threshold temperature sensitivity. This may be due to the quality of the interface between the cSiGe layer and the dielectric layer which is quantified by the channel defectivity or interface trap density (Dit) in the PMOS devices.

Accordingly, there is a need for improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a partial cross-sectional view of a semiconductor wafer structure including a semiconductor layer having a first crystalline structure;

FIG. 2 illustrates processing subsequent to FIG. 1 where a masking layer is formed over NMOS areas of the semiconductor wafer structure that will be used to form NMOS devices;

FIG. 3 illustrates processing subsequent to FIG. 2 after a thin, forward graded epitaxial SiGe layer is selectively formed over PMOS areas of the semiconductor wafer structure that will be used to form PMOS devices;

FIG. 4 illustrates processing subsequent to FIG. 3 after a silicon cap layer is formed over the forward graded epitaxial SiGe layer;

FIG. 5 illustrates processing subsequent to FIG. 4 after metal gate electrodes are formed in the NMOS and PMOS areas;

FIG. 6 illustrates processing subsequent to FIG. 5 after first source/drain regions are implanted in the NMOS and PMOS areas;

FIG. 7 illustrates processing subsequent to FIG. 6 after second source/drain regions are implanted in the NMOS and PMOS areas around implant spacers; and

FIG. 8 graphically represents the profile concentrations of germanium in an exemplary PMOS device which includes a channel region formed with a graded SiGe layer and a cap silicon layer.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A semiconductor fabrication process and resulting integrated circuit are described for manufacturing high performance PMOS transistor devices on a semiconductor wafer substrate which is used to form both PMOS and NMOS devices. By forming a thin silicon cap layer (e.g., approximately 15 Angstroms) over a compressively stressed SiGe layer (e.g., approximately 50 Angstroms) that is thinner than a critical relaxation thickness, the channel stress conditions of the PMOS devices may be selectively controlled in a semiconductor wafer to produce an integrated circuit having stress conditions that are favorable for both NMOS and PMOS devices. In selected embodiments, PMOS devices with improved mobility are formed on silicon substrate having a <100> channel orientation (i.e., on 45 degree rotated wafer or substrate) by forming PFET transistor devices on an epitaxially grown layer of biaxially compressive, forward graded silicon germanium and a thin, counter-doped silicon cap layer. With a biaxially compressive channel SiGe layer that is thinner than a first threshold thickness measure and a counter-doped silicon cap layer that is thicker than a second threshold thickness measure, a substantial enhancement in DC performance is achieved (e.g., up to at least 23-35% improvement in observed mobility, depending on the germanium doping profile in the compressive SiGe layer) as compared to PMOS devices formed with an uncapped compressive SiGe channel layer. By forward grading the amount of germanium in the SiGe to peak at the interface with the silicon cap layer, the compressive SiGe layer functions to control the valence band so as to induce quantum confinement for the holes, thereby lowering the threshold voltage and the subthreshold slope. In selected embodiments, a lower threshold voltage is achieved to different degrees, depending on the germanium doping profile in the compressive SiGe layer and the thickness of the silicon cap layer. With the various disclosed embodiments, PMOS transistors formed on a semiconductor substrate having a <100> channel orientation are provided with strain enhanced channel regions, even though conventional <100> oriented silicon substrates have not been considered to be sensitive to stressing.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

Referring now to FIG. 1, there is shown a partial cross-sectional view of a semiconductor wafer structure 1. The structure 1 includes a semiconductor layer 12 formed on or as part of a semiconductor substrate 10 that has a first crystallographic orientation. Also illustrated is a shallow trench isolation 14 that divides the layer 12 into separate regions. Depending on the type of transistor device being fabricated, the semiconductor layer 10, 12 may be implemented as a bulk silicon substrate, single crystalline silicon (doped or undoped), semiconductor on insulator (SOI) substrate, or any semiconductor material including, for example, Si, SiC, SiGe, SiGeC, Ge, GaAs, InAs, InP, as well as other III/V or II/VI compound semiconductors or any combination thereof, and may optionally be formed as the bulk handling wafer. The semiconductor layer 10, 12 has a channel crystallographic orientation of <100>. Although not shown, the materials of layer 12 for NMOS and PMOS device areas 96, 97 may be different. And for any FET type (NMOS or PMOS), the layer 12 may consist of multiple stacks of materials. Of note is that although bulk type of substrate is shown here for the description of the invention, the invention is not limited to any specific substrate type. For example, the starting substrate for the invention can be of semiconductor-on-insulator (SOI) type having a buried insulator layer under a top layer of semiconductor.

The isolation regions or structures 14 are formed to electrically isolate the NMOS device area(s) 96 from the PMOS device area(s) 97. Isolation structures 14 define lateral boundaries of an active region or transistor region 96, 97 in active layer 12, and may be formed using any desired technique, such as selectively etching an opening in the second semiconductor layer 12 using a patterned mask or photoresist layer (not shown), depositing a dielectric layer (e.g., oxide) to fill the opening, and then polishing the deposited dielectric layer until planarized with the remaining second semiconductor layer 12. Any remaining unetched portions of the patterned mask or photoresist layer(s) are stripped.

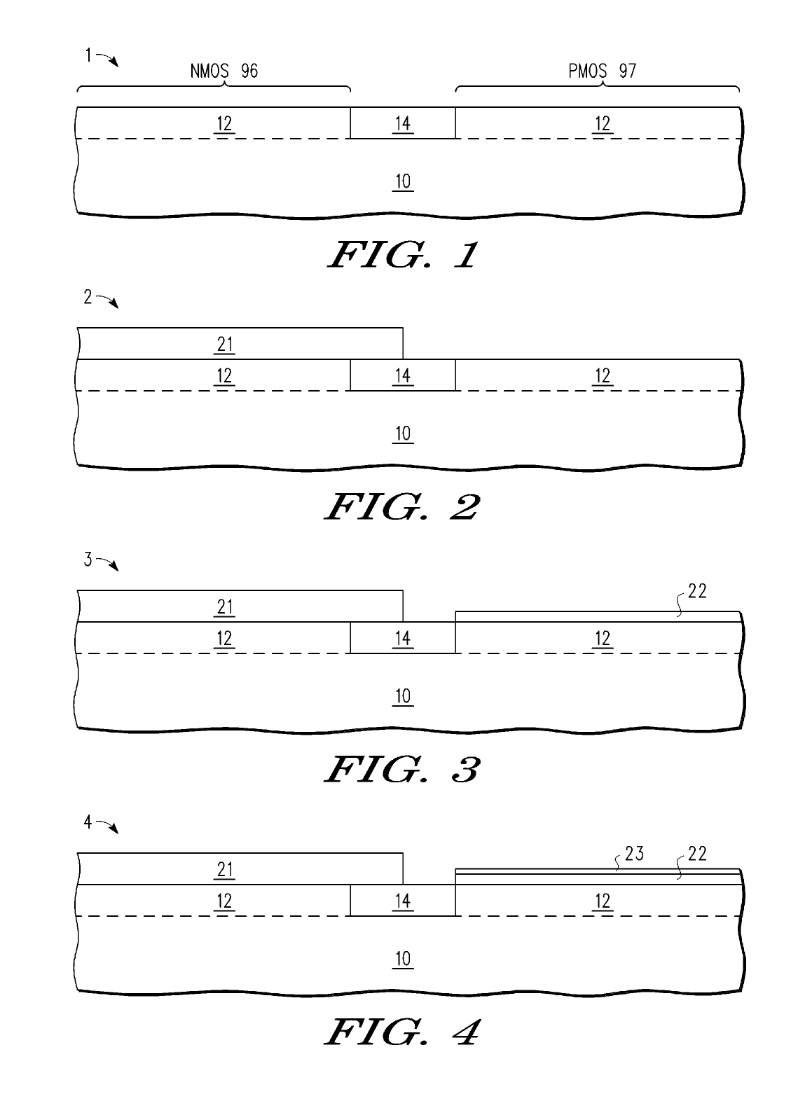

FIG. 2 illustrates processing of a semiconductor wafer structure 2 subsequent to FIG. 1 where a masking layer 21 is selectively formed over NMOS areas 96 of the semiconductor wafer structure that will be used to form NMOS devices. For example, one or more masking layers 21 (e.g., an oxide layer and/or nitride layer) may be deposited and/or grown over the semiconductor wafer structure, and then conventional patterning and etching techniques may be used to form an opening in the mask layer(s) 21 that exposes at least the PMOS device area 97. The selectively formed masking layer 21 is used to define and differentiate active regions for NMOS and PMOS devices subsequently formed on the wafer structure 12.

FIG. 3 illustrates processing of a semiconductor wafer structure 3 subsequent to FIG. 2 after a thin, compressively stressed semiconductor layer 22 is selectively formed over the PMOS area(s) 97 of the semiconductor wafer structure that will be used to form PMOS devices. In selected embodiments, the thin, compressively stressed semiconductor layer 22 is formed with a semiconductor material having larger atom-to-atom spacing than the underlying second semiconductor layer 12, such as SiGe, SiGeC, or combinations and composition by weight thereof, which is capable of being formed utilizing a selective epitaxial growth method or other deposition methods accompanied by subsequent re-crystallization. For example, if PMOS devices are formed over the semiconductor layer 12 in the PMOS area 97 and the semiconductor material for layer 12 is silicon, the semiconductor layer 22 may be formed by epitaxially growing a SiGe layer that is thinner than a critical relaxation thickness to form a compressive SiGe layer 22 having a lattice spacing the same as the semiconductor layer 12. This epitaxial growth may be achieved by a process of chemical vapor deposition (CVD) at a chamber temperature between 400 and 900° C. in the presence of dichlorosilane, germane (GeH₄), HCl, and hydrogen gas. So long as the thickness of the SiGe layer 22 is below the critical relaxation thickness, the SiGe layer 22 is compressively stressed. As will be appreciated, the critical relaxation thickness for a SiGe layer will depend on the amount of germanium contained in the layer 22, though in an example embodiment, an epitaxially grown SiGe layer 22 that is approximately 50 Angstroms or less will have a uniform compressive stress. Because the lattice spacing of the silicon germanium is normally larger than the lattice spacing of the underlying silicon semiconductor layer 12, one advantage of forming the semiconductor layer 22 with compressive silicon germanium is that there is no stress induced on the silicon semiconductor layer 12. Another advantage of forming a relatively thin semiconductor layer 22 is to minimize the step height difference between the finally formed NMOS and PMOS device areas 96, 97, thereby improving processing uniformity between the two areas.

In selected implementations, the formation of the semiconductor layer 22 with silicon germanium may be provided with a uniform grading or concentration of germanium as a function of depth. In these implementations, the concentration of germanium in the semiconductor layer 22 is constant across the entire thickness of the semiconductor layer 22. In other implementations, the germanium concentration of the semiconductor layer 22 is forward graded so that there is a lower concentration of germanium in the lower part of the semiconductor layer 22 (e.g., nearer to the interface with the underlying semiconductor layer 12) and a higher concentration of germanium in the upper part of the semiconductor layer 22. In one example, the concentration of germanium is approximately 30% (e.g., 37%) at the top of the semiconductor layer 22 and is gradually reduced to 0% at the bottom of semiconductor layer 22. However, other embodiments may have other graded germanium profiles, where the concentration of germanium at the upper part of the semiconductor layer 22 may range from 100% germanium to 10% germanium, and the concentration germanium at the lower part of the semiconductor layer 22 may range from 0-20%. In yet other embodiments, the semiconductor layer 22 may have different germanium concentrations at both the top and bottom portions.

FIG. 4 illustrates processing of a semiconductor wafer structure 4 subsequent to FIG. 3 after a thin, semiconductor layer 23 is selectively formed over the epitaxial SiGe layer 22 in the PMOS area(s) 97 of the semiconductor wafer structure that will be used to form PMOS devices. In selected embodiments, the thin, semiconductor layer 23 is formed by epitaxially growing or depositing a layer of silicon to a predetermined thickness of approximately 15 Angstroms over the underlying SiGe layer 22, though other thicknesses and materials may be used. This epitaxial growth may be achieved by heating the semiconductor wafer structure 4 to a temperature between 500 and 900° C. in the presence of dichlorosilane, hydrogen chloride and hydrogen gas. The presence of the silicon cap layer 23 in the PMOS devices increases the threshold voltage and the subthreshold slope while it improves mobility as compared to an un-capped SiGe channel region by providing a silicon/dielectric interface that has lower channel defectivity or interface trap density (Dit). And as will be appreciated, the degree of performance enhancement may be affected by the thickness of the silicon cap layer 23. For example, a relatively thin silicon cap layer 23 (e.g., approximately 5 Angstroms) will enhance the mobility gain by 13% for a PMOS metal gate and high-k dielectric layer on a silicon cap layer and constant grade SiGe layer 22, and will enhance the mobility gain by 23% for a PMOS metal gate and high-k dielectric layer on a silicon cap layer and a forward graded SiGe layer 22 (as compared to a conventionally formed PMOS metal gate and high-k dielectric layer on a silicon substrate). However, a thicker silicon cap layer 23 (e.g., approximately 15 Angstroms) will enhance the mobility gain by 23% for a PMOS metal gate and high-k dielectric layer on a silicon cap layer and constant graded SiGe layer 22, and will enhance the mobility gain by 35% for a PMOS metal gate and high-k dielectric layer on a silicon cap layer and forward graded SiGe layer 22 (as compared to a conventionally formed PMOS metal gate and high-k dielectric layer on a silicon substrate).

In selected embodiments, the semiconductor layer 23 is formed as a counter-doped layer 23 using p-type dopants (e.g. Boron or Indium) having a conductivity type that is opposite the conductivity type of the underlying substrate. For example, in the PMOS region 97, the PMOS semiconductor layer 12 as originally formed is lightly doped with n-type impurities. In this case, the semiconductor layer 23 may be counter-doped to a predetermined p-type conductivity level by performing in-situ doping during epitaxial growth of the semiconductor layer 23. In addition or in the alternative, p-type impurities (e.g., boron) may be implanted following formation of epitaxial silicon layer 23.

As formed, the compressive SiGe layer 22 serves as a template layer for growing or depositing the silicon cap layer 23 in the PMOS area(s) 97, and the subsequent processing is controlled to prevent the compressive SiGe layer 22 from relaxing in such a way as would change the stress condition of the silicon cap layer 23.

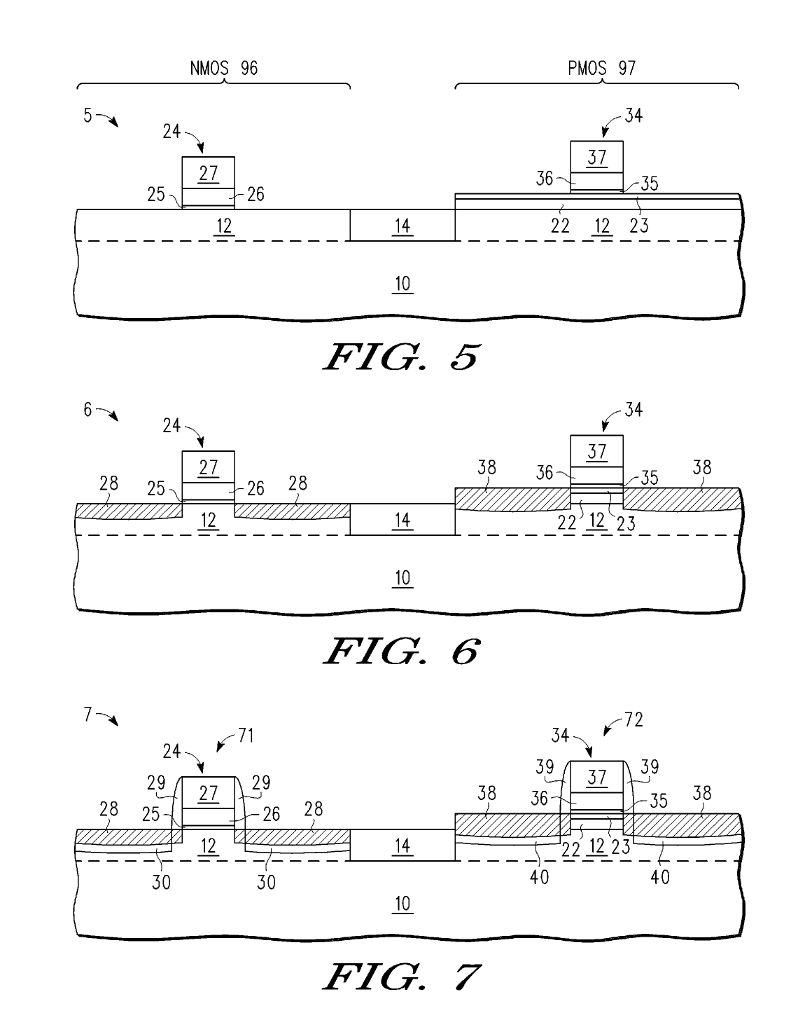

FIG. 5 illustrates processing of a semiconductor wafer structure 5 subsequent to FIG. 4 after the mask layer 21 is removed, and metal gate electrodes 24, 34 are formed in the NMOS and PMOS areas 96, 97, respectively. As illustrated, NMOS metal gate electrode 24 includes one or more gate dielectric layers 25, a metal-based conductive layer 26 overlying the gate dielectric 25, and a polysilicon layer 27 formed on the metal-based layer 26. In similar fashion, PMOS metal gate electrode 34 includes one or more gate dielectric layers 35, a metal-based conductive layer 36 overlying the gate dielectric 35, and a polysilicon layer 37 formed on the metal-based layer 36. Gate dielectric layer(s) 25, 35 may be formed by depositing or growing an insulator or high-k dielectric over the NMOS substrate layer 12 and/or PMOS substrate layer 23 using chemical vapor deposition (CVD), plasma-enhanced chemical vapor deposition (PECVD), physical vapor deposition (PVD), atomic layer deposition (ALD), thermal oxidation, or any combination(s) of the above to a predetermined final thickness in the range of 0.1-10 nanometers, though other thicknesses may be used. While the gate dielectric layer(s) 25, 35 may be formed with insulator materials (such as silicon dioxide, oxynitride, nitride, nitride SiO₂, SiGeO₂, GeO₂, etc.), other suitable materials include metal oxide compounds such as hafnium oxide (preferably HfO₂), though other oxides, silicates or aluminates of zirconium, aluminum, lanthanum, strontium, tantalum, titanium and combinations thereof may also be used, including but not limited to Ta₂O₅, ZrO₂, HfO₂, TiO₂, Al₂O₃, Y₂O₃, La₂O₃, HfSiN_{y}Oₓ, ZrSiN_{y}Oₓ, ZrHfOx, LaSiOₓ, YSiOₓ, ScSiOₓ, CeSiOₓ, HfLaSiOₓ, HfAlOₓ, ZrAlOₓ, and LaAlOₓ. In addition, multi-metallic oxides (for example barium strontium titanate, BST) may also provide high-k dielectric properties.

After forming the gate dielectric layer(s) 25, 35, an unetched gate stack is formed using any desired metal gate stack formation sequence. For example, one or more conductive layers are sequentially deposited or formed over the gate dielectric layer(s) 25, 35 to form a first gate stack that includes at least (doped or undoped) semiconductor layer 27, 37 formed over a metal-based conductive layers 26, 36. In one embodiment, the one or more metal or metal-based layers 26, 36 are formed using any desired deposition or sputtering process, such as CVD, PECVD, PVD, ALD, molecular beam deposition (MBD) or any combination(s) thereof. The metal-based conductive layers 26, 36 include an element selected from the group consisting of Ti, Ta, Ir, Mo, Ru, W, Os, Nb, Ti, V, Ni, and Re. In selected embodiments, the metal-based conductive layer 36 may be formed with a metal or metal-based layer that has a mid-gap work function that is suitable for NMOS and PMOS transistors, such as by depositing a TiN layer having a thickness of 20-100 Angstroms, though other metallic gate layer materials (such as Al, W, HfC, TaC, TaSi, ZrC, Hf. etc.) or even a conductive metal oxide (such as IrO₂), and different thicknesses, may be used. In addition or in the alternative, the metal-based conductive layer 26 may be formed with a metal or metal-based layer that has a work function that is suitable for a PMOS transistor. As will be appreciated, the metal-based conductive layers 26, 36 may be formed from one or more layers.

After depositing the metal-based conductive layer(s) 26, 36, a heavily doped (e.g., n+) polysilicon layer 27, 37 may be formed using CVD, PECVD, PVD, ALD, or any combination(s) thereof to a thickness in the range of approximately 1-200 nanometers, though other materials and thicknesses may be used. As deposited, the polysilicon layer 27, 37 may be formed as an undoped or lightly doped layer having relatively low conductivity or current flow, in which case the conductivity in the polysilicon layer is established with one or more subsequent doping or implantation steps. However, it will be appreciated, that the polysilicon layer 27, 37 may be formed as a heavily doped layer having relatively high conductivity, in which case the conductivity in the polysilicon layer may be reduced in a predetermined region of the silicon-containing layer by counter-doping with one or more subsequent doping or implantation steps. As deposited, the polysilicon layer 27, 37 can be formed in an initial amorphous or polycrystalline state, but it will be in a polycrystalline state after subsequent annealing steps in the device integration. The material(s) for the polysilicon layer 27, 37 can be silicon, silicon-germanium, or other suitable semiconductors.

Once the unetched gate stack is formed, NMOS gate electrode layers 25-27 and PMOS gate electrode layers 35-37 are selectively etched to form the NMOS metal gate electrode(s) 24 and PMOS metal gate electrode(s) 34. As will be appreciated, the metal gate electrodes 24, 34 may be formed using any desired pattern and etching processes, including application and patterning of photoresist directly on the semiconductor layer 27, 37, or using a multi-layer masking technique to sequentially forming a first anti-reflective coating (ARC) layer, a second masking layer (such as a hardmask or TEOS layer) and a photoresist layer (not shown) which is patterned and trimmed to form a resist pattern over the intended gate electrodes 24, 34. The first ARC layer will act as a hard mask when the semiconductor layers 27, 37 and metal-based conductive layers 26, 36 are subsequently etched. In turn, the second masking layer will serve as a hard mask for the etching of the first ARC layer, and the photoresist layer may be formed from any appropriate photoresist material (e.g., 193 nm resist) that is patterned (e.g., using a 193 nm develop) and etched to form a resist pattern over the second masking layer.

FIG. 6 illustrates processing of a semiconductor wafer structure 6 subsequent to FIG. 5 after first source/drain regions 28, 38 are implanted in the NMOS and PMOS areas 96, 97, respectively. As illustrated, the first source/drain regions 28, 38 may be formed by first masking the PMOS area 97 and implanting exposed portions of the NMOS area 96 (including the semiconductor layer 12) with a first n-type implant to form the lightly doped extension regions 28. Separately, the NMOS area 96 may be masked and exposed portions of the PMOS area 97 (including the semiconductor layer 12, compressively stressed SiGe layer 22, and the silicon cap layer 23) may be implanted with p-type impurities to form the lightly doped extension regions 38 in the transistor areas 97. Though not shown, the implantation steps may be used to implant the gate electrodes 24, 34.

FIG. 7 illustrates processing of a semiconductor wafer structure 7 subsequent to FIG. 6 after second source/drain regions 30, 40 are implanted in the NMOS and PMOS areas 96, 97 around implant spacers 29, thereby forming NMOS and PMOS transistor(s) 71, 72. As depicted, one or more sidewall spacers 29 are formed on at least the sidewalls of the gate electrodes 24, 34 by depositing and anisotropically etching one or more spacer dielectric layers which may include an offset or spacer liner layer (e.g., a deposited or grown silicon oxide), alone or in combination with an extension dielectric layer. With the sidewall spacers 29 in place, an implant mask may be formed over the PMOS area 97 to expose the transistor area 96 to an implantation which forms the NMOS source/drain regions 28. Likewise, an implant mask may be formed over the NMOS area 96 to expose the transistor area 97 to an implantation which forms the PMOS source/drain regions 38 around the PMOS gate electrode 34 and sidewall spacers 29. As illustrated, NMOS transistor 71 includes one or more gate dielectric layers 25, a conductive NMOS gate electrode 26, 27 overlying the gate dielectric 25, sidewall spacers 29 formed from one or more dielectric layers on the sidewalls of NMOS gate electrode, and source/drain regions 28, 30 formed in the NMOS active layer 12. In similar fashion, PMOS transistor 72 includes one or more gate dielectric layers 35, a conductive PMOS gate electrode 36, 37 overlying the gate dielectric 35, sidewall spacers 39 formed from one or more dielectric layers on the sidewalls of PMOS gate electrode, and source/drain regions 38, 40 formed in the PMOS active layers 12, 22, 23. Though not shown, it will be appreciated, that the NMOS and PMOS transistors 71, 72 may include silicide layers in the source/drain regions and gate electrodes.

At the point in the fabrication process shown in FIG. 7, the PMOS transistor device 72 is formed over a semiconductor layer 12, a biaxially compressive SiGe channel layer 22, and a silicon cap layer 23. Thus, the PMOS active region includes a compressively stressed epitaxial silicon germanium layer 22 (formed over the semiconductor layer 12 in the PMOS area 97) that exhibits biaxial compressive stress in both the length (a.k.a. channel) axis and width axis directions and an unstressed silicon cap layer 23 which, in accordance with selected embodiments, improves the carrier mobility (and thus the performance) of the PMOS transistor(s) 72.

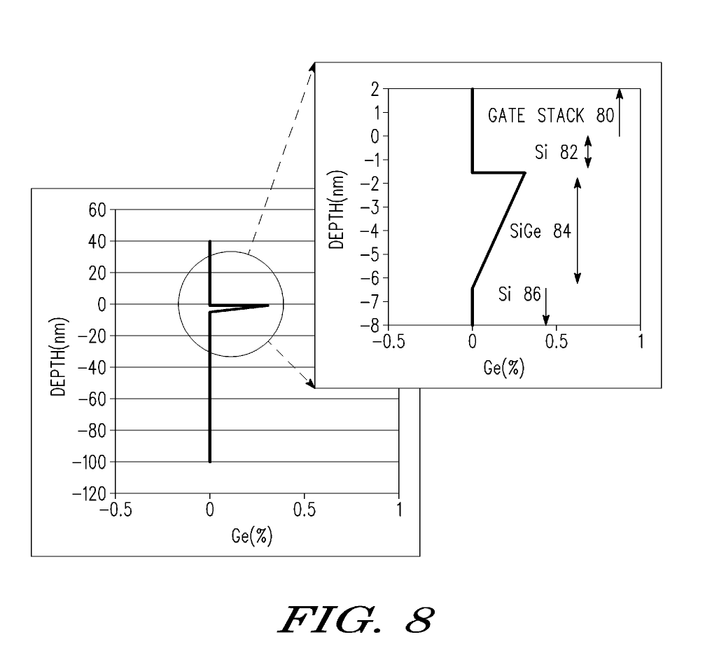

The various embodiments of the present invention described herein may be used to form PMOS active layer from a graded silicon germanium substrate layer and silicon cap layer to improve hole mobility for PMOS transistors while simultaneously reducing the threshold voltage and subthreshold slope. In fabricating the PMOS active layer, the compressively stressed SiGe layer is formed so that the germanium content is graded from a first relatively low germanium concentration (at the interface with the underlying substrate layer) to a second relatively high germanium concentration (at the interface with the overlying silicon cap). This grading is illustrated in FIG. 8 which graphically represents the profile concentrations of germanium in an exemplary PMOS device which includes a channel region formed with a graded SiGe layer and a cap silicon layer. As depicted, the gate electrode/dielectric stack 80 is formed over an active layer substrate which is formed as a combination of a silicon cap layer 82, forward graded SiGe layer 84 and underlying silicon substrate layer 86. As depicted, the concentration of germanium is 0% at the bottom of SiGe layer 84 and is gradually increased to 30% at the top of SiGe layer 84 before dropping back to 0% in the silicon cap layer 82.

To form an optimized PMOS transistor as part of a CMOS fabrication process, a biaxially strained semiconductor layer (e.g., a silicon layer exhibiting biaxial tensile stress) having any desired channel orientation is formed as an active layer over a buried oxide layer and separated into NMOS and PMOS active layers by an isolation structure. After masking off the NMOS active layer, the PMOS active layer may be implanted with silicon or xenon to relax the strained semiconductor layer in the PMOS region. On the relaxed PMOS active layer having a <100> channel orientation, PMOS transistor devices with improved mobility are formed by epitaxially growing a thin layer (e.g., approximately 50 Angstroms) of biaxially compressive silicon germanium (SiGe) layer with a germanium concentration that is forward graded, and then epitaxially growing a thin silicon cap layer on the compressive SiGe layer. By limiting the thickness of the SiGe layer to be less than the critical relaxation thickness threshold, the SiGe layer has a compressive stress state. Thereafter, NMOS and PMOS transistor devices are formed over the strained semiconductor layer in the NMOS area and the compressively stressed SiGe and silicon cap layers in the PMOS area. Being fabricated on a biaxial-tensile strained substrate, the NMOS devices have improved carrier mobility. With a biaxially compressive channel formed from the compressively stressed SiGe and silicon cap layers, improved device performance is obtained for the PMOS devices.

After completion of source/drain implant processing and dopant activation annealing, the semiconductor wafer structure is completed into a functioning device. Examples of different processing steps which may be used to complete the fabrication of the depicted gate electrode structures into functioning transistors include, but are not limited to, one or more sacrificial oxide formation, stripping, extension implant, halo implant, spacer formation, source/drain implant, source/drain anneal, contact area silicidation, and polishing steps. In addition, one or more stressed contact etch stop layers over the NMOS and PMOS transistor(s) 71, 72 to further (differentially) stress the NMOS and PMOS channel regions. Finally, conventional backend processing (not depicted) typically including multiple levels of interconnect is then required to connect the transistors in a desired manner to achieve the desired functionality. Thus, the specific sequence of steps used to complete the fabrication of the gate transistors 71, 72 may vary, depending on the process and/or design requirements.

By now, it should be appreciated that there has been provided herein a semiconductor fabrication process for forming a PMOS field effect transistor device. In the disclosed process, a wafer is provided that includes at least a first semiconductor layer, either alone as a bulk substrate or in combination with an underlying buried insulating layer as part of an SOI substrate. On at least a part of the first semiconductor layer, a compressive second semiconductor layer of silicon germanium is formed, such as by epitaxially growing silicon germanium to a predetermined thickness that is less than a critical relaxation thickness threshold for silicon germanium. For example, the compressive layer of silicon germanium may be epitaxially grown to a thickness of between approximately 30 and 50 Angstroms. In selected embodiments, the compressive second semiconductor layer is formed by epitaxially growing a graded layer of silicon germanium in which the concentration of germanium increases as the second semiconductor layer is formed. For example, the graded silicon germanium layer may have a first concentration of germanium of approximately 30-40% at a top portion that is gradually reduced to approximately 0-10% at a bottom portion. After forming the compressive second semiconductor layer, a third semiconductor layer of silicon is formed on the second semiconductor layer. For example, the third semiconductor layer of silicon may be epitaxially grown to a thickness of between approximately 5 and 15 Angstroms. In addition, the third semiconductor layer of silicon may be counter-doped to have a first conductivity type that is opposite to a second conductivity type of the first semiconductor layer below the PMOS gate structure. Finally, at least a PMOS gate structure, such as a high-k dielectric and a metal gate electrode, is formed over the third semiconductor layer to define a PMOS transistor channel region which includes at least a portion of the compressive second semiconductor layer below the PMOS gate structure. [035] In another form, there is provided herein a CMOS fabrication process for forming a semiconductor integrated circuit. In the disclosed process, a semiconductor layer is formed as a bulk or SOI substrate which has a PMOS device portion and an NMOS device portion. On the PMOS device portion of the semiconductor layer, a biaxially compressive silicon germanium layer is epitaxially grown to a predetermined thickness that is less than a critical relaxation thickness threshold for silicon germanium (e.g., to a thickness of between approximately 30 and 50 Angstroms). Subsequently, a silicon layer is epitaxially grown on the silicon germanium layer (e.g., to a thickness of between approximately 5 and 15 Angstroms). In selected embodiments, the silicon layer is counter-doped to have a first conductivity type that is opposite to a second conductivity type of the first semiconductor layer. Thereafter, NMOS and PMOS gate structures are formed. As formed, the PMOS gate structure overlies the silicon layer to define a PMOS transistor channel region in a portion of the silicon layer and the biaxially compressive silicon germanium layer below the PMOS gate structure. In addition, the NMOS gate structure is formed to overly the NMOS device portion of the first semiconductor layer to define a NMOS transistor channel region in the first semiconductor layer below the NMOS gate structure. In selected embodiments, the silicon germanium layer is epitaxially grown as a graded layer of silicon germanium in which a concentration measure of germanium is higher in a portion of the silicon germanium layer that is closer to the silicon layer, and is lower in a portion of the silicon germanium layer that is closer to the first semiconductor layer. For example, the graded layer of silicon germanium may have a first concentration of germanium of approximately 30-40% at a top portion of the silicon germanium layer that is gradually reduced to approximately 0-10% at a bottom portion of the silicon germanium layer.

In yet another form, there is provided a semiconductor device and method for fabricating same, where the semiconductor device includes a silicon substrate layer have a PMOS device portion on which is formed a forward graded compressive silicon germanium layer and an epitaxial silicon layer which may be formed as a counter-doped silicon layer over the silicon germanium layer. The semiconductor device also includes a PMOS gate structure overlying the epitaxial silicon layer to define a PMOS transistor channel region in a portion of the epitaxial silicon layer and the compressive silicon germanium layer below the PMOS gate structure. In addition, source and drain regions are formed in the substrate adjacent to the PMOS transistor channel region. In selected embodiments, the source/drain regions are epitaxially grown silicon germanium source/drain regions.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A semiconductor fabrication process for forming a PMOS field effect transistor device, comprising:
providing a wafer comprising a first semiconductor layer;
forming a compressive second semiconductor layer of silicon germanium which is forward graded with germanium on at least part of the first semiconductor layer;
forming a third semiconductor layer of counter-doped silicon on the compressive second semiconductor layer; and
forming at least a PMOS gate structure overlying the third semiconductor layer to define a PMOS transistor channel region, the PMOS transistor channel region comprising at least a portion of the compressive second semiconductor layer below the PMOS gate structure.

2. The process of claim 1, where providing a wafer comprises providing a wafer comprising a first semiconductor layer formed over an insulating layer.

3. The process of claim 1, where forming the compressive second semiconductor layer comprises epitaxially growing silicon germanium to a predetermined thickness that is less than a critical relaxation thickness threshold for silicon germanium.

4. The process of claim 1, where forming the compressive second semiconductor layer comprises epitaxially growing a graded layer of silicon germanium in which the concentration of germanium increases as the second semiconductor layer is formed.

5. The process of claim 1, where forming a compressive second semiconductor layer comprises epitaxially growing a graded layer of silicon germanium having a concentration of germanium of at least 1-10% at a bottom portion of the compressive second semiconductor layer that is gradually increased to approximately 30-40% at a top portion of the compressive second semiconductor layer.

6. The process of claim 1, where forming the compressive second semiconductor layer comprises epitaxially growing a compressive layer of silicon germanium to a thickness of between approximately 30 and 50 Angstroms.

7. The process of claim 1, where forming the third semiconductor layer of silicon comprises epitaxially growing a layer of silicon to a thickness of between approximately 5 and 15 Angstroms.

8. The process of claim 1, where forming the third semiconductor layer of counter-doped silicon comprises epitaxially growing a layer of silicon having a first conductivity type that is opposite to a second conductivity type of the first semiconductor layer below the PMOS gate structure.

9. The process of claim 1, where the PMOS gate structure comprises a high-k dielectric and a metal gate electrode.

10. A CMOS fabrication process for forming a semiconductor integrated circuit, comprising:
providing a first semiconductor layer comprising a PMOS device portion and an NMOS device portion;
epitaxially growing a biaxially compressive silicon germanium layer which is forward graded with germanium on the PMOS device portion and not on the NMOS portion of the first semiconductor layer;
forming a counter-doped silicon layer on the biaxially compressive silicon germanium layer; and
forming PMOS and NMOS gate structures, comprising:
at least a PMOS gate structure overlying the silicon layer to define a PMOS transistor channel region, the PMOS transistor channel region comprising at least a portion of the silicon layer and the biaxially compressive silicon germanium layer below the PMOS gate structure, and
at least an NMOS gate structure overlying the NMOS device portion of the first semiconductor layer to define a NMOS transistor channel region in the NMOS device portion of the first semiconductor layer below the NMOS gate structure.

11. The CMOS fabrication process of claim 10, where providing the first semiconductor layer comprises forming the first semiconductor layer formed over an insulating layer.

12. The CMOS fabrication process of claim 10, where epitaxially growing the biaxially compressive silicon germanium layer comprises epitaxially growing the biaxially compressive silicon germanium layer to a predetermined thickness that is less than a critical relaxation thickness threshold for silicon germanium.

13. The CMOS fabrication process of claim 10, where epitaxially growing the biaxially compressive silicon germanium layer comprises epitaxially growing a graded layer of silicon germanium in which a concentration measure of germanium is higher in a portion of the silicon germanium layer that is closer to the silicon layer, and is lower in a portion of the silicon germanium layer that is closer to the first semiconductor layer.

14. The CMOS fabrication process of claim 10, where epitaxially growing the biaxially compressive silicon germanium layer comprises epitaxially growing a graded layer of silicon germanium having a concentration of germanium of at least 1-10% at a bottom portion of the silicon germanium layer that increases to approximately 30-40% at a top portion of the silicon germanium layer.

15. The CMOS fabrication process of claim 10, where epitaxially growing the biaxially compressive silicon germanium layer comprises epitaxially growing the biaxially compressive silicon germanium layer to a thickness of between approximately 30 and 50 Angstroms.

16. The CMOS fabrication process of claim 10, where epitaxially growing the silicon layer comprises epitaxially growing the silicon layer to a thickness of between approximately 5 and 15 Angstroms.

17. The CMOS fabrication process of claim 10, where forming a counter doped silicon layer comprises epitaxially growing a counter-doped silicon layer having a first conductivity type that is opposite to a second conductivity type of the first semiconductor layer below the PMOS gate structure.

18. A semiconductor device comprising:
a silicon substrate layer;
a forward graded compressive silicon germanium layer formed over a PMOS device portion of the substrate;
an epitaxial silicon layer formed over the compressive silicon germanium layer; and
a PMOS gate structure overlying the epitaxial silicon layer to define a PMOS transistor channel region in a portion of the epitaxial silicon layer and compressive silicon germanium layer below the PMOS gate structure; and
source and drain regions formed in the substrate adjacent to the PMOS transistor channel region.

19. The semiconductor device of claim 18, where the PMOS gate structure comprises a high-k dielectric and a metal gate electrode.

20. The semiconductor device of claim 18, where the epitaxial silicon layer is a counter-doped epitaxial silicon layer.
